(19) United States
(12) Patent Application Publication
(10) Pub. No.: US 2025/0075369 A1
(43) Pub. Date: Mar. 6, 2025

(54) METHOD AND APPARATUS FOR GAS DELIVERY IN A PROCESSING CHAMBER

(71) Applicant: Applied Materials, Inc., Santa Clara, CA (US)

(72) Inventors: Ryan Sungbin HU, Santa Clara, CA (US); Kuan Chien SHEN, Sunnyvale, CA (US); Kazuyoshi KOBASHI, Santa Clara, CA (US); Chen-Yao CHAO, Santa Clara, CA (US); Masato ISHII, Sunnyvale, CA (US)

(21) Appl. No.: 18/238,810

(22) Filed: Aug. 28, 2023

(51) Int. Cl. C30B 25/16; H01L 21/02

(52) U.S. Cl. CPC C30B 25/165; H01L 21/02211; H01L 21/02271

(57) ABSTRACT

Disclosed herein are a gas delivery module, a processing chamber, and a method for depositing a film on a substrate. In one example, a gas delivery module is provided that includes a deposition precision flow device (PFD) flow controller, a carrier PFD flow controller, and a plurality of mass flow controllers (MFCs). The deposition PFD flow controller is configured to control a flow of a deposition gas through a plurality of outlets. The carrier PFD flow controller is configured to control a flow of a carrier gas through a plurality of outlets. The first MFC of the plurality of MFCs includes a first inlet and an outlet. The first inlet of the first MFC is fluidly coupled to a first outlet of the plurality of outlets of the deposition PFD and to a first outlet of the plurality of outlets of the carrier PFD. The second MFC of the plurality of MFCs includes a second inlet and an outlet. The second inlet of the second MFC is fluidly coupled to a second outlet of the plurality of outlets of the deposition PFD and to a second outlet of the plurality of outlets of the carrier PFD. The third MFC of the plurality of MFCs includes a third inlet and an outlet. The third inlet of the third MFC is fluidly coupled to a third outlet of the plurality of outlets of the deposition PFD and to a third outlet of the plurality of outlets of the carrier PFD.

### BACKGROUND

### Field

The present disclosure relates to components and epitaxial system that includes precision gas delivery system comprised of a plurality of flow controllers and inlets, and more specifically to system and method for depositing a film on a substrate. In one or more embodiments, the gas delivery system facilitates the gas flow for processing a substrate in a processing chamber.

### Description of the Related Art

Semiconductor substrates are processed for a wide variety of applications, including the fabrication of integrated devices and microdevices. One method of processing substrates includes deposing a material, such as a semiconductor or conductive material on a surface of a substrate. Epitaxy is one deposition process that refers to processes used to grow a thin crystalline layer (epi layer) on a crystalline substrate. The epi layer on a semiconductor substrate facilitates formation of highly complex microprocessors and memory devices.

Non-uniformities can exist for gas flow, for example, gas concentrations, gas temperatures, and/or flow rates. Gas properties, such as temperature and expansion, gas concentration, and flow rate, can affect control and adjustability, thermal uniformity and deposition uniformity, such as center-to-edge film thickness uniformity. Complex operations can further exacerbate existing issues from non-uniformities and lack of control of gas properties. Precise control of the concentration, flow rate and injection location into the processing chamber is lacking in conventional designs.

Thus, a need exists for an improved apparatus and methods for reliably controlling gas flow for processing a substrate in a processing chamber.

### SUMMARY

Disclosed herein are a gas delivery module, a processing chamber, and a method for depositing a film on a substrate. In one example, a gas delivery module is provided that includes a deposition precision flow device (PFD) flow controller, a carrier PFD flow controller, and a plurality of mass flow controllers (MFCs). The deposition PFD flow controller is configured to control a flow of a deposition gas through a plurality of outlets. The carrier PFD flow controller is configured to control a flow of a carrier gas through a plurality of outlets. The first MFC of the plurality of MFCs includes a first inlet and an outlet. The first inlet of the first MFC is fluidly coupled to a first outlet of the plurality of outlets of the deposition PFD and to a first outlet of the plurality of outlets of the carrier PFD. The second MFC of the plurality of MFCs includes a second inlet and an outlet. The second inlet of the second MFC is fluidly coupled to a second outlet of the plurality of outlets of the deposition PFD and to a second outlet of the plurality of outlets of the carrier PFD. The third MFC of the plurality of MFCs includes a third inlet and an outlet. The third inlet of the third MFC is fluidly coupled to a third outlet of the plurality of outlets of the deposition PFD and to a third outlet of the plurality of outlets of the carrier PFD.

In yet another example, a processing chamber is provided that includes a chamber body, a plurality of optically transparent windows, a susceptor, and a gas delivery module. The transparent windows are disposed on the chamber body and with the body, partially enclosing a processing volume. The susceptor is disposed in the processing volume. The gas delivery module provided includes a deposition precision flow device (PFD) flow controller, a carrier PFD flow controller, and a plurality of mass flow controllers (MFCs). The deposition PFD flow controller is configured to control a flow of a deposition gas through a plurality of outlets. The carrier PFD flow controller is configured to control a flow of a carrier gas through a plurality of outlets. The first MFC of the plurality of MFCs includes a first inlet and an outlet. The first inlet of the first MFC is fluidly coupled to a first outlet of the plurality of outlets of the deposition PFD and to a first outlet of the plurality of outlets of the carrier PFD. The second MFC of the plurality of MFCs includes a second inlet and an outlet. The second inlet of the second MFC is fluidly coupled to a second outlet of the plurality of outlets of the deposition PFD and to a second outlet of the plurality of outlets of the carrier PFD. The third MFC of the plurality of MFCs includes a third inlet and an outlet. The third inlet of the third MFC is fluidly coupled to a third outlet of the plurality of outlets of the deposition PFD and to a third outlet of the plurality of outlets of the carrier PFD.

In still another example, a method for depositing a film on a substrate is provided that includes directing a deposition gas into a deposition PFD flow controller; directing a carrier gas into a carrier gas PFD flow controller; outputting the deposition gas from the PFD flow controller into a first set of independent output channels; outputting the carrier gas from the PFD flow controller into a second set of independent output channels different than the first set; merging each channel of the first set of output channels with a corresponding channel of the second set of output channels; directing the merged channels to respective MFCs; outputting gas from each MFC to a respective injection channel of processing chamber; and depositing a film on a substrate in the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic top view of a processing system, according to embodiments of the present application.

FIG. 2 is a schematic cross-sectional view of an epitaxial deposition processing chamber, according to embodiments of the present application.

FIG. 3. is a schematic top view of chamber body of the processing apparatus shown in FIG. 2.

FIG. 4 is a schematic view of a gas delivery system of the epitaxial deposition processing chamber of FIG. 2.

FIG. 5 is a schematic block diagram view of a method of processing substrates for semiconductor manufacturing, according to an embodiment of the present application.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Disclosed herein are a processing chamber, a gas flow system, and a method for depositing a film on a substrate. The apparatus and method both utilize a precision gas delivery system to inject gas through an inlet of an epitaxial deposition chamber, or other suitable processing chamber. In one example, the flow of each a deposition gas and a carrier gas are controlled independently by precision flow device (PFD) flow controllers, which are directed into separate channels in an inlet into an epitaxial deposition chamber by mass flow controllers (MFC). The MFCs are configured to direct the flow of the deposition gas and the carrier gas into multiple channels to evenly distribute (e.g., spatially) the deposition gases over the substrate to facilitate uniform deposition.

When a processing a semiconductor substrate in an epitaxial deposition chamber, maintaining uniform deposition across the surface of a semiconductor substrate can be challenging. Flow of the deposition gas impacts deposition rate and uniformity, and a large gradient in the flow of the deposition gas across the substrate can cause the epitaxial layer to have relatively large variations in terms of thickness and electrical resistivity throughout the deposited material.

According to an embodiment of the present application, PFDs are fluidly coupled to a plurality of MFCs in a gas delivery module fluidly coupled to a plurality of inlet openings of the processing chamber. The openings are spaced at intervals along a semicircular portion of the processing chamber. The gas delivery module, by way of the MFCs, flows a precise amount of each the deposition gas and the carrier gas through each inlet opening based on a variety of parameters including gas concentration, deposition rate, and gas expansion. The gas mixture containing the deposition gas and a carrier gas is precisely flowed into the chamber by the MFCs of the gas delivery module such that the concentration of the deposition material to be deposited on the substrate is controllable throughout the epitaxial deposition chamber.

According to a general aspect of the present application, a carrier gas is precisely mixed with a deposition gas by PFDs and is injected into a plurality of MFCs prior to entrance into the epitaxial deposition chamber. The deposition containing gas can include, for example, one or more reactive gasses. In some examples, the deposition gas may be silicon and/or germanium containing gasses, or other suitable reactive gases, such as silane (SiH₄), disilane (Si₂H₆), dichlorosilane (SiH₂Cl₂), trichlorosilane, and/or germane (GeH₄), chlorine containing etching gases, such as hydrogen chloride (HCl), and/or dopant gases, such as phosphine (PH₃) and/or diborane (B₂H₆). The deposition gas is then used to processes the substrate by, for example, depositing a film on a substrate, or selectively etching the substrate.

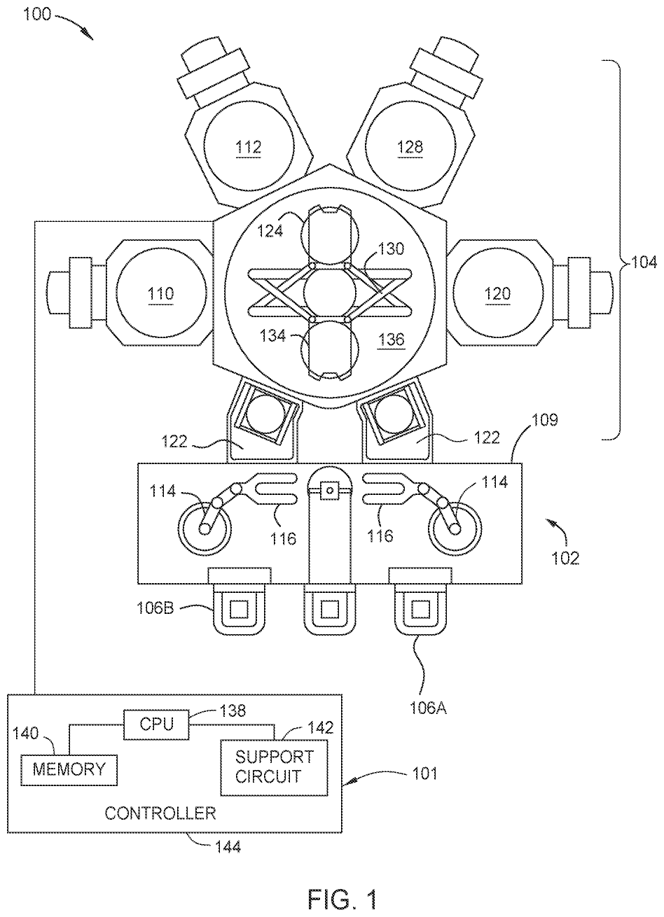

Turning now to FIG. 1, FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 is a CENTURA® integrated processing system, commercially available from Applied Materials, Inc., located in Santa Clara, California. It is contemplated that other processing systems (including those from other manufacturers) may be adapted to benefit from the disclosure.

The platform 104 includes a plurality of processing chambers 110, 112, 120, 128, and the one or more load lock chambers 122 that are coupled to a transfer chamber 136. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122.

In one or more embodiments, the factory interface 102 includes at least one docking station 109 and at least one factory interface robot 114 to facilitate the transfer of substrates. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment or ambient environment, such as atmospheric environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, 128.

The controller 144 is coupled to the processing system 100 and is used to control processes and methods, such as the operations of the methods described herein (for example the operations of the method 800). The controller 144 includes a central processing unit (CPU) 138, a memory 140 containing instructions, and support circuits 142 for the CPU. The controller 144 controls various items directly, or via other computers and/or controllers.

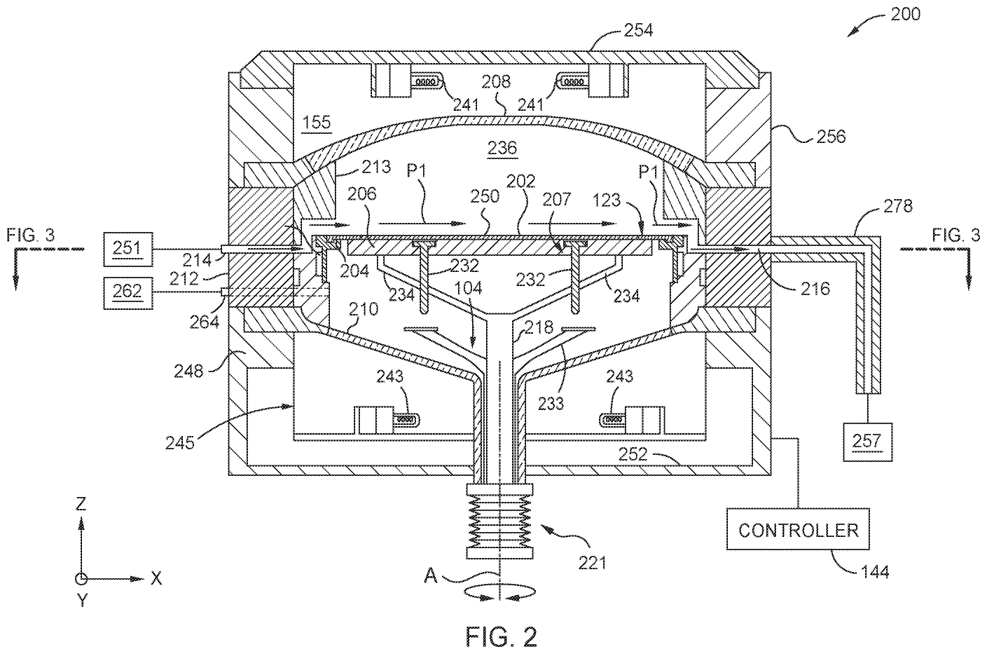

FIG. 2 illustrates a schematic cross-sectional view of an epitaxial deposition processing chamber 200 according to an embodiment. The epitaxial deposition processing chamber may be used in place of any of processing chambers 110, 112, 120, 128. The epitaxial deposition processing chamber 200 is a deposition chamber configured for growth of an epitaxial layer on a substrate 202. A controller 144 is in communication with the processing chamber 200 and is used to control processes performed in, and function of, the processing chamber 200. The controller 144 may be a slave of the controller 144 illustrated in FIG. 1, or may be an integral component (hardware of software) of the controller 144.

The processing chamber 200 includes an upper body 256, a lower body 248 disposed below the upper body 256, and a chamber body 212 disposed between the upper body 256 and the lower body 248. An upper window 208 (such as an upper dome) and a lower window 210 (such as a lower dome) are disposed on the upper and lower surfaces of the chamber body 212 to enclose a processing volume 204. The windows 208, 210 are generally substantially transparent to radiant energy at predetermined wavelengths. A susceptor 206 is disposed in the processing volume 236 and configured to support a substrate 202 thereon during processing.

A plurality of upper heat sources 241 are disposed in the upper body 256 above the upper window 208 and below a lid 254 enclosing the upper body 256. The plurality of upper heat sources 241 are configured to direct radiant energy through the upper window 208 toward the susceptor 206 and a top surface 250 of the substrate 202 disposed thereon. Similarly, a plurality of lower heat sources 243 are disposed below the lower window 210. The plurality of lower heat sources 243 are configured to direct radiant energy through the lower window 210 toward the bottom of the susceptor 206.

According to an embodiment, the heat sources 241, 243 are lamps that are capable of generating infrared radiation. Other heat sources that are capable of generating infrared radiation are contemplated, such as resistive heaters, light emitting diodes (LEDs), and/or lasers.

The plurality of lower heat sources 243 are disposed between the lower window 210 and a chamber floor 252. The plurality of lower heat sources 243 form a portion of a lower heating module 245. The upper window 208 is an upper dome and is formed at least partially of an energy transmissive material, such as quartz. The lower window 210 is a lower dome and is formed at least partially of an energy transmissive material, such as quartz.

The susceptor 206 is supported in the processing chamber by a plurality of arms 234 coupled to an inner shaft 218. The inner shaft 218 is coupled to a motion assembly 221 includes one or more actuators and/or motors that provide vertical and/or rotational movement of the inner shaft 218, which, in turn, moves susceptor 206 and the substrate 202 disposed thereon. Lift pin holes 207 are formed through the susceptor 206 and are each sized to accommodate lift pins 232 that is used to lift the substrate 202 during substrate transfer into and out of the chamber body 212 through a slit valve. The relative elevation of the inner shaft 218 may be changed to cause a lift pins stop 233 to displace the lift pins 232 through the susceptor 206, thus lifting the substrate 202 above the susceptor 206 to allow access by a robot blade (not shown) that moves the substrate 202 into and out of the processing chamber 200.

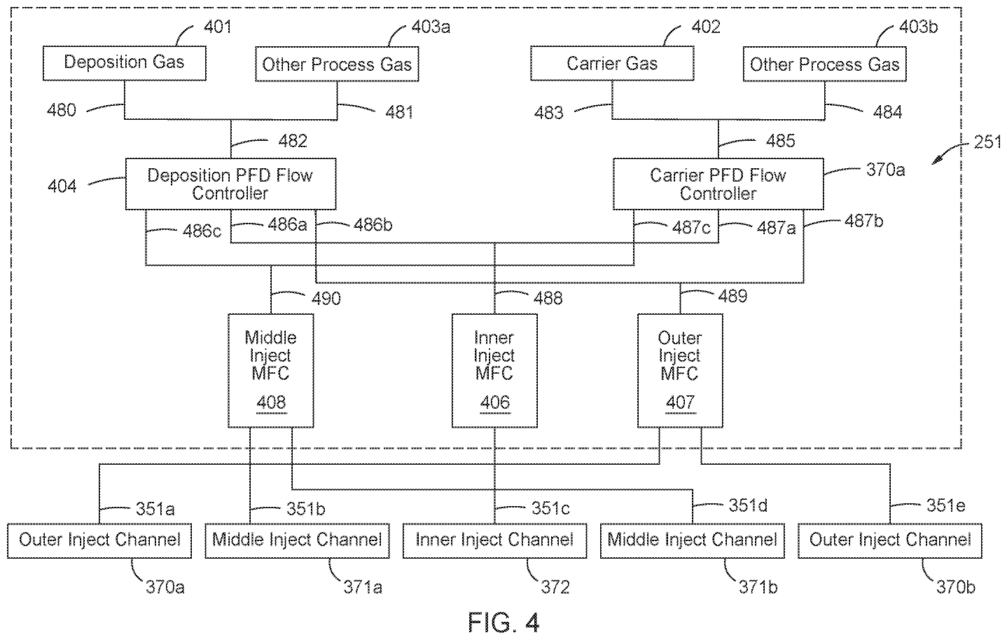

The chamber body 212 includes a plurality of gas inlets 214, a plurality of purge gas inlets 264, and one or more gas exhaust outlets 216. The plurality of gas inlets 214 are generally aligned in a horizontal plane, but it is contemplated that plurality of gas inlets 214 may be aligned in an array. The gas inlets 214 are connected with a gas delivery system 251 (shown in more detail in FIG. 4) and provides a cross-flow of processing gases across the top surface 250 of the substrate 202. A liner 213 (which may include separable upper and lower portions) is positioned radially inward of the chamber body 212. The liner 213 includes one or more gas passages 215 formed therein to facilitate process gas flow into the processing volume 236 along gas flow path P1.

The gas delivery system 251 generally provides a deposition gas, etchant gas, doping gas, and/or carrier gas to an upper surface of the substrate 202. In one example, the plurality of gas inlets 214 are disposed at an elevation above or coplanar with the susceptor 206 when the substrate is in an elevated (e.g., deposition) processing position. The purge gas inlets 264 are connected with a purge gas source 262 and provide purge gas to the epitaxial deposition processing chamber 200 to reduce backside deposition on the substrate 202.

The plurality of gas inlets 214 and the plurality of purge gas inlets 264 are disposed on the opposite side of the chamber body 212 from the one or more gas exhaust outlets 216. The one or more gas exhaust outlets 216 are connected an exhaust conduit 278. The exhaust conduit 278 fluidly connects the one or more gas exhaust outlets 216 formed through the chamber body 212 to an exhaust pump 257 that evacuates the processing volume 236 and gases flowing into the processing volume 236 from at least the gas inlets 214.

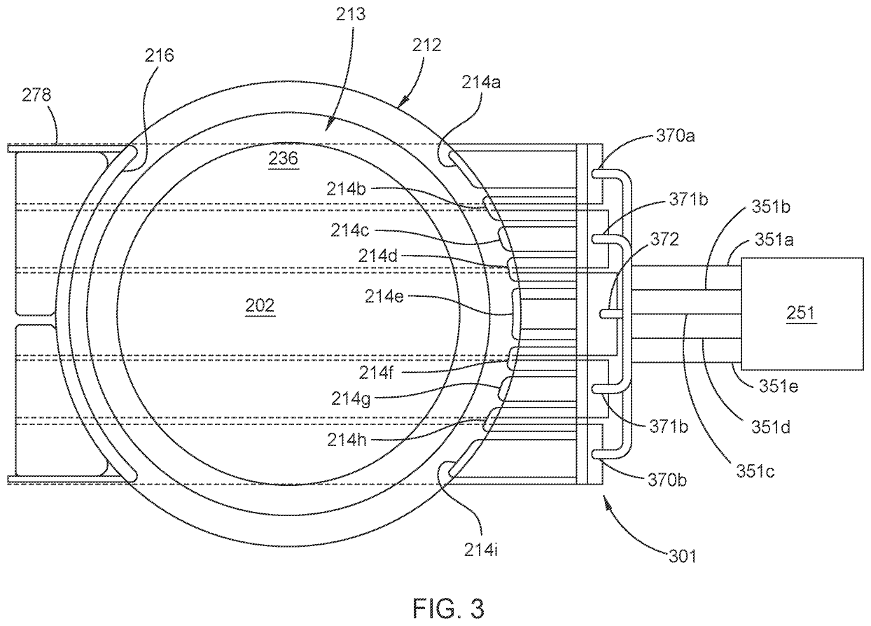

FIG. 3 illustrates a top schematic view of a chamber body shown in FIG. 2, according to one or more embodiments.

The chamber body 212 is a ring shape, with an inner wall that engages the liner 213. The liner 213 is exposed to and defines the processing volume 236. The chamber body 212 has plurality of gas inlets 214a-214i (more or less openings are contemplated) formed through a wall of the chamber body 212 to facilitate process gas ingress to the processing volume 236. An insert 301, such as an injector, is coupled to the base of the chamber body 212. The insert 301 may be bolted to and/or disposed in a corresponding recess of the chamber body 212 to facilitate coupling between the chamber body 212 and the insert 301. The insert 301 includes a plurality of guide channels therein (for example, 5 channels-one central, two middle, and two outer) which direct process gases to the plurality of gas inlets 214a-214i.

The gas delivery system 251 is coupled to the insert 301 by a plurality of conduits 351a-351e. The plurality of conduits 35a-351e allow for independent flow control of a center zone 372, middle zones 371a-371b, and outer zones 370a-370b of the insert 301. The independent control of the center zone 372, middle zones 371a-371b, and outer zones 370a-370b allows for improved uniformity of the process gases to the processing region 313, thereby improving deposition uniformity on the substrate 202. While five conduits 351a-351e are shown (corresponding to five zones), it is contemplated that more or less conduits (and thus more or less zones) may be utilized depending on the level of uniformity control that is desired. The insert 301 is located opposite of (e.g., 180 degrees from) exhaust outlet 216 and exhaust conduit 278.

While not shown, the chamber body 212 may include an opening formed therein to facilitate ingress and egress of the substrate 202 into the processing volume 236. In such an example, the opening is a slit valve which is selectively opened and closed via a slit valve door. In one example, the slit valve is approximately 90 degrees from a centerline of the insert 301.

FIG. 4 is a block diagram of a gas delivery system 251 of the epitaxial deposition processing chamber 200 of FIG. 2, according to an embodiment of the present application. The gas delivery system 251 includes a deposition gas source 401, a carrier gas source 402, and optionally one or more other gas sources 403a, 403b (two are shown, but is contemplated that a single gas source 403 may be utilized). Additionally, the gas delivery system 251 includes a plurality of precision flow device (PFD) flow controllers 404, 405, as well as a plurality of mass flow controllers (MFCs) 406-408. PFDs can be used to divide volumetric gas flow into a controllable ratio. Although PFDs are disclosed herein, a number of devices can be used to divide volumetric gas flow into a controllable ratio, such as a flow divider. MFCs can be used to measure the mass and/or volume flow and temperature of a gas through the line. Although MFCs are disclosed herein, any type of flow controller can be used, such as back pressure controllers or volumetric flow controllers, or any other device that can measure and control the mass and/or volume flow and temperature of a gas through a line. In one example, the carrier gas provided by the carrier gas source 402 is mixed with processing gas provided by the process gas source 403b prior to delivery to the gas inlets 214, such as by way of a conduit upstream of the plurality of PFDs 404, 405 and MFCs 406-408 or by way of the plurality of PFDs 404, 405. Similarly, in another example, the deposition gas provided by the deposition gas source 401 is mixed with processing gas provided by the process gas source 403a prior to delivery to the gas inlets 214, such as by way of a conduit upstream of the plurality of PFDs 404, 405 and MFCs 406-408 or by way of the plurality of PFDs 404, 405.

The deposition gas source 401 and the other process gas source 403a each have a respective output 480, 481 coupled to an input of a PFD flow controller 404 via common line 482. While the deposition gas of the deposition gas source 401 and the other process gas of the other process gas source 403a are mixed before the input of the deposition PFD flow controller 404, it is contemplated that alternatively the deposition gas of the deposition gas source 401 and the other process gas of the other process gas source 403a are mixed at the input of the deposition PFD flow controller 404.

The carrier gas source 402 and the other process gas source 403b each have a respective output 483, 484 coupled to an input of a PFD flow controller 405 via a common line 485. While the carrier gas of the carrier gas source 402 and the other process gas of the other process gas source 403b are illustrated as mixed before the input of the carrier PFD flow controller 405 it is contemplated, the carrier gas of the carrier gas source 402 and the other process gas of the other process gas source 403 may alternatively be mixed at the input of the carrier PFD flow controller 405.

The deposition PFD flow controller 404 is downstream of the deposition gas source 401 and the other process gas source 403a. The deposition PFD flow controller 404 is configured to control parameters of the flow of the mixture of the deposition gas other process gases. For example, the deposition PFD flow controller 404 controls the flow rate and/or the concentration of deposition gas by adjusting the flow rate of deposition gas from the deposition gas source 401 and other process gases from the other process gas source 403a.

The carrier PFD flow controller 405 is located downstream of the carrier gas source 402 and the other process gas source 403b. The carrier PFD flow controller is configured to control parameters of the flow of the mixture of the carrier gas optionally other process gases. For example, the carrier PFD flow controller 405 controls the flow rate and/or concentration of carrier gas from the carrier gas source 402 and other process gas from the other process gas source 403b.

Each PFD flow controller 404, 405 has a plurality of outputs configured to control the output flow of respective gas mixtures therefrom. The outputs of the PFD flow controllers 404, 405, are configured to interface with a plurality of MFCs. In some embodiments, each PFD flow controller 404, 405 has a plurality of outputs, wherein each output of the PFD flow controller 404, 405 flows the gas mixture to one of the plurality of MFCs. In the embodiment shown in FIG. 4, each PFD flow controller 404, 405 has three outputs. For example, the outputs 486a-486c from the PFD flow controller 404 are fluidly coupled to respective MFCs 406, 407, and 408. Similarly, the outputs 487a-487c from the PFD flow controller 404 are fluidly coupled to respective MFCs 406, 407, and 408

In some examples, the volumetric ratio of gases provided to the plurality of MFCs 406, 407, 408 are different. In one instance, an amount of deposition gas mixture provided from the deposition PFD flow controller 404 to the plurality of MFCs 406, 407, 408 is greater than an amount of carrier gas mixture provided from the carrier PFD flow controller to the plurality of MFCs 406, 407, 408. In another instance, an amount of deposition gas mixture provided from the deposition PFD flow controller to the plurality of MFCs 406, 407, 408 is less than an amount of carrier gas mixture provided from the carrier PFD flow controller to the plurality of MFCs 406, 407, 408. In other embodiments, each of the MFCs 406, 407, 408 receives a different volumetric flow rate of gas from the deposition PFD flow controller 404 and the carrier PFD flow controller 405, thus facilitating uniform film deposition. During operation, deposition gas mixture from the deposition PFD flow controller 404 and carrier gas mixture from the carrier PFD flow controller 405 are merged into a common conduit 488 upstream of the MFC 406. Similarly, deposition gas mixture from the deposition PFD flow controller 404 and carrier gas mixture from the carrier PFD flow controller 405 are merged into a common conduit 489, 490 upstream of the MFCs 407, 408, respectively.

Each MFC 406, 407, 408 is configured to control parameters of the flow of the gas mixture, such as flow rate and temperature. Each MFC 406-408 has at least one output configured to flow the gas mixture into an inject channel of a processing chamber. In some embodiments, each MFC 406-408 may have two or more outputs configured to flow the gas mixture into respective inject channels. In the embodiment shown in FIG. 4, outer inject MFC 407 and middle inject MFC 408 each have two outputs, and inner inject MFC 406 has one output. Specifically, the MFC 406 has a single outlet coupled to an inner inject channel 372 by a conduit 351c. The MFC 408 has two independent outlets coupled to the middle inject channels 371a, 371b by respective conduits 351b. 351d. The MFC 407 has two independent outlets coupled to the outer inject channels 370a, 370b by respective conduits 351a, 351e. The independent channels between the MFCs 406-408 and the inject channels 370a, 370b, 371a, 371b, and 372 facilitate enhanced process gas control, resulting in improved deposition uniformity.

Each MFC 406, 407, 408 is configured to be operable independently of each other MFC 406, 407, 408. By way of example, the inner inject MFC 406 can flow one hundred percent of the total gas flow into the inner inject channel 409 and into the processing chamber 200, while the outer inject MFC 407 and middle inject MFC 408 flow zero percent of the total gas flow into the processing chamber 200. In yet another embodiment the ratio of total gas flow into the processing chamber may be split 20% of the total gas flow from the inner inject MFC 406 into the inner inject channel 409, 30% of the total gas flow from the middle inject MFC 408 into the middle inject channels 411 and 50% of the total gas flow from the outer inject MFC 407 into the outer inject channels 410. In yet another embodiment the ratio of total gas flow into the processing chamber may be split 5% of the total gas flow from the inner inject MFC 406 into the inner inject channel 409, 30% of the total gas flow from the middle inject MFC 408 into the middle inject channels 411 and 65% of the total gas flow from the outer inject MFC 407 into the outer inject channels 410. Other flow ratios are also contemplated, and the above examples are included for illustration and are not intended to be limiting. In some embodiments the flow ratios are determined by trials run with test wafers. The rations can be adjusted for recipes based on the trial deposition film measurements.

As the gas flows into the gas delivery module 310, the PFDs and MFCs are operable to control the concentration and flow rate of the gases flowing into the processing volume 236 through the gas delivery module. Moreover, the PFDs are operable to control the concentration of the deposition gas output into each MFC over time and independent of each other MFC. In one embodiment, the deposition PFD flow controller 404 can output a concentration of deposition gas to the inner inject MFC 406 that is less than the concentration of deposition gas that is output to the middle inject MFC 408 and outer inject MFC 407. In another embodiment, the deposition PFD flow controller 404 and carrier PFD flow controller 405 can output a concentration of the deposition gas 401 and the carrier gas 402 to the MFCs 406, 407, 408 that is changeable over time. In yet another embodiment, the deposition PFD flow controller 404 and carrier PFD flow controller 405 can output a modifiable concentration of the deposition gas 401 and the carrier gas 402 to each of the MFCs 406, 407, 408 independently of the each other MFC 406, 407, 408, changeable based on controlled processing parameters or in real time based on observed properties and parameters inside of the processing volume 236.

Gas properties can dictate the movement and functions of the gas, which can change due to the environment, such as the temperature, the pressure, and the volume of the gas. Depending on the environment inside of the processing chamber 200, the deposition gas 401 and the carrier gas 402 will have different properties and the gas molecules will excite, expand, contract, and move in certain ways. The system and method, such as shown and described herein, provides for improved processing uniformity by flowing the deposition gas 401 and the carrier gas 402 in based at least in part on the gas properties, to account for downstream non-uniformities. In some embodiments the parameters of the plurality of PFD flow controllers and MFCs is determined in advance of processing a substrate in a chamber. In some embodiments, the gas flow controlled by the deposition PFD flow controller 404, the carrier PFD flow controller 405, the inner inject MFC 406, the outer inject MFC 407, and the middle inject MFC 408 is determined in advance of processing by a simulated procedure to determine settings of each device. In some embodiments the gas flow controlled by the deposition PFD flow controller 404, the carrier PFD flow controller 405, the inner inject MFC 406, the outer inject MFC 407, and the middle inject MFC 408 is changeable throughout processing, such as real time modifications to the parameters. The flexibility to adjust the concentration of deposition gas 401 to carrier gas 402 by way of the PFD flow controllers 404, 405, and the flow rate into each inject channel 370a-b, 371a-b, 372 allows for tunability of the system based on the gas properties in the processing volume 236 to enable improved uniformity of the deposition on the substrate. In some examples, the deposition gas has a greater influence on film growth rate and/or deposition rate than a carrier gas. In some examples, the expansion of the gas in the processing volume 236 from one of the inject channels 370, 371, 372 may expand into another of the inject channels 370, 371, 372 (or flow path thereof) due to a pressure differential in the chamber. In some embodiments, individual control of each a deposition PFD flow controller 404 and a carrier PFD flow controller 405 allows for adjustment of the gas expansion by compensating total gas flow through each channel with an increased ratio of carrier gas to deposition gas in the total gas flow. Thus, gas expansion can be controlled between inject channels without alteration of the deposition gas distribution, resulting in improved processing uniformity.

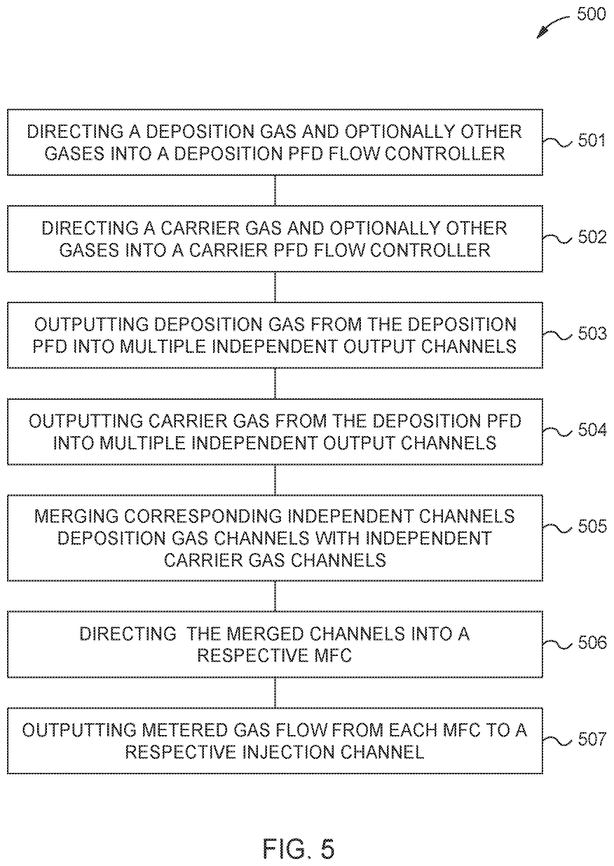

FIG. 5 is a schematic block diagram view of a method 500 of processing substrates for semiconductor manufacturing, according to an embodiment of the present application. Method 500 begins at operation 501, in which a deposition gas and optionally other gases are directed into a deposition PFD flow controller. Similarly, in operation 502, a carrier gas and optionally other gases are directed into a carrier PFD flow controller. The PFD flow controllers facilitate enhanced control of volumetric flow rates and concentrations over standard valving/meters (or when using MFCs alone), particular in light of elevated temperatures which can occur during semiconductor manufacturing, thereby improving deposition uniformity.

In operation 503, deposition gas from the deposition PFD flow controller is output into multiple independent output channels. Similarly, carrier gas from the carrier PFD flow controller is output into multiple independent output channels in operation 504. In operation 505, each output channel from the deposition PFD flow controller is merged with an output channel of the carrier PFD flow controller. The merged channels have more accurate flow rates and concentrates than conventional systems due to the use of the PFDs.

In operation 506, the merged channels are then directed into respective MFCs. The outputs of the MFCs are then provided to injection channels of an epitaxial deposition chamber to facilitate film formation on a substrate.

The use of both PFDs and MFCs during the injection process results in increased gas concentration control and flow uniformity, which ultimately results in more uniformity deposition. By independently controlling the concentration of the deposition gas from the carrier gas into each inject channel, the uniformity of gas flow inside of the processing volume can be tuned precisely based on the parameters inside of the processing volume. Independent PFD flow controllers for a deposition gas and a carrier gas allow for a precise flow rate of each respective gas into an MFC controlling the gas flow into the chamber. Deposition rate can be affected by a variety of parameters including, for example, temperature, hardware configuration, gas concentration, and gas velocity. Based on the parameters of the gas and inside the processing volume, independent control of the deposition gas flow rate and the carrier gas flow rate, the ratio of deposition gas to carrier gas, and the channel of the flow of gas into the processing volume may be adjusted to compensate for the parameters and to control the direction of gas expansion between inject channels. As gas expansion occurs, and other parameters change during the processing of a substrate, the control of gas concentration via independent PFD flow controllers for each gas source, and control of gas flow into channels of the chamber via independent MFCs allows for precise tunability and uniform deposition. In some embodiments, the control of the gas via the PFD flow controllers and the MFCs are changeable during the process of deposition. In some embodiments, the control of the gas via the PFD flow controllers and the MFCs are set by a recipe determined in advance of the deposition process.

Is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A gas delivery module, comprising;
a deposition flow divider (FD) flow controller configured to control a flow of deposition gas through a plurality of outlets of the deposition FD;
a carrier FD flow controller configured to control a flow of carrier gas through a plurality of outlets of the carrier FD; and
a plurality of flow controllers (FCs), the plurality of flow controllers comprising:
a first FC having a first inlet and an outlet, the first inlet of the first FC fluidly coupled to a first outlet of the plurality of outlets of the deposition FD and to a first outlet of the plurality of outlets of the carrier FD;
a second FC having a second inlet and an outlet, the first inlet fluidly coupled to a second outlet of the plurality of outlets of the deposition FD and to a second outlet of the plurality of outlets of the carrier FD; and
a third FC having a third inlet and an outlet, the third inlet fluidly coupled to a third outlet of the plurality of outlets of the deposition FD and to a third outlet of the plurality of outlets of the carrier FD.

2. The gas delivery module of claim 1, wherein the deposition FD comprises three outlets.

3. The gas delivery module of claim 1, wherein the carrier FD comprises three outlets.

4. The gas delivery module of claim 1, wherein the deposition FD has an inlet configured to receive deposition gas from a deposition gas source and another gas from another gas source.

5. The gas delivery module of claim 1, wherein the carrier FD has an inlet configured to receive carrier gas from a carrier gas source and another gas from another gas source.

6. The gas delivery module of claim 1, wherein the first FC comprises a plurality of outlets.

7. The gas delivery module of claim 1, wherein the second FC comprises a plurality of outlets.

8. The gas delivery module of claim 1, wherein the third FC comprises a plurality of outlets.

9. A processing chamber, suitable for use in semiconductor manufacturing, comprising:
a chamber body;
a plurality of optically transparent windows coupled to the chamber body and defining and processing volume;
a susceptor disposed in the processing volume; and
a gas delivery module, comprising;
a deposition flow divider (FD) flow controller configured to control a flow of deposition gas through a plurality of outlets of the deposition FD;
a carrier FD flow controller configured to control a flow of carrier gas through a plurality of outlets of the carrier FD; and
a plurality of flow controllers (FCs), the plurality of flow controllers comprising:
a first FC having a first inlet and a first inlet and an outlet, the first inlet of the first FC fluidly coupled to a first outlet of the plurality of outlets of the deposition FD and to a first outlet of the plurality of outlets of the carrier PFD;
a second FC having a second inlet and an outlet, the first inlet fluidly coupled to a second outlet of the plurality of outlets of the deposition FD and to a second outlet of the plurality of outlets of the carrier FD; and
a third FC having a third inlet and an outlet, the third inlet fluidly coupled to a third outlet of the plurality of outlets of the deposition FD and to a third outlet of the plurality of outlets of the carrier FD.

10. The processing chamber of claim 9, further comprising a plurality of inject channels, where each inject channel is coupled to the outlet of one of the first FC, the second FC, or the third FC.

11. The processing chamber of claim 10, wherein two inject channels of the plurality of inject channels are both coupled to the outlet of the second FC.

12. The processing chamber of claim 11, wherein the two inject channels of the plurality of inject channels are both outer inject channels of an injector insert.

13. The processing chamber of claim 12, wherein two additional inject channels of the plurality of inject channels are both coupled to the outlet of the third FC.

14. The processing chamber of claim 13, wherein the additional two inject channels of the plurality of inject channels are both middle inject channels of the injector insert.

15. A method of depositing a film on a substrate, comprising:
directing a deposition gas into a deposition FD flow controller;
directing a carrier gas into a carrier gas FD flow controller;
outputting the deposition gas from the FD flow controller into a first set of independent output channels;
outputting the carrier gas from the FD flow controller into a second set of independent output channels different than the first set;
merging each channel of the first set of output channels with a corresponding channel of the second set of output channels;
directing the merged channels to respective FCs;
outputting gas from each FC to a respective injection channel of processing chamber; and
depositing a film on a substrate in the processing chamber.

16. The method of claim 15, wherein the directing the merged channels to respective FCs comprises directing the merged channels to three FCs.

17. The method of claim 15, wherein the deposition gas comprises silane, disilane, or trisilane.

18. The method of claim 15, further comprising combining the deposition gas with another gas in a conduit upstream of the deposition FD.

19. The method of claim 18, further comprising combining the carrier gas with another gas in a second conduit upstream of the carrier FD.

20. The method of claim 15, wherein a center injection channel of the processing chamber is coupled to a single FC.
